(19) United States
(12) Patent Application Publication
(10) Pub. No.: US 2008/0054366 A1
(43) Pub. Date: Mar. 6, 2008

(54) CMOS semiconductor device having tensile and compressive stress films

(75) Inventor: Sergey Pidin, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/790,956

(22) Filed: Apr. 30, 2007

(30) Foreign Application Priority Data
Sep. 6, 2006 (JP) 2006-242087

(51) Int. Cl. H01L 27/092; H01L 21/8238

(52) U.S. Cl. 257/371; 438/223; 257/E21.633; 257/E21.642; 257/E27.067

(57) ABSTRACT

A CMOS semiconductor device includes: an isolation region formed in the surface layer of a semiconductor substrate to define an NMOSFET active region and a PMOSFET active region adjacent to each other; an NMOSFET structure formed in the NMOSFET active region; a PMOSFET structure formed in the PMOSFET active region; a tensile stress film covering the NMOSFET structure; and a compressive stress film covering the PMOSFET structure, wherein a border between the tensile stress film and the compressive stress film is set nearer to the PMOSFET active region than the NMOSFET active region along a gate width direction. A performance of a CMOS semiconductor device can be improved by the layout of the tensile and compressive stress films.

### CROSS REFERENCE TO RELATED APPLICATION

This application is based on and claims priority of Japanese Patent Application No. 2006-242087 filed on Sep. 6, 2006, the entire contents of which are incorporated herein by reference.

### BACKGROUND OF THE INVENTION

A) Field of the Invention

The present invention relates to a CMOS semiconductor device and its manufacture method, and more particularly to a CMOS semiconductor device having a nitride film formed above a semiconductor substrate and its manufacture method.

B) Description of the Related Art

Mobility of charge carriers in semiconductor is effected by stress. For example, mobility of electrons in silicon increases as tensile stress along electron motion direction increases, and decreases as compressive stress increases. Conversely, mobility of positive holes in silicon increases as compressive stress along electron motion direction increases, and decreases as tensile stress increases.

A semiconductor device manufacture process includes generally a process of forming a metal oxide semiconductor (MOS) transistor structure, covering the MOS transistor structure with an interlayer insulating film, and thereafter forming contact holes through the interlayer insulating film to expose electrode regions of the MOS transistor. In order to form contact holes with good controllability, an interlayer insulating film is made with an etching stopper film and an insulating film formed thereon. A silicon nitride film mainly presenting tensile stress is used as the etching stopper film.

With high integration of integrated circuit devices, constituent electronic components such as metal oxide semiconductor (MOS) transistors are made fine. As devices are made finer, influence of stress in an etching stopper film or the like upon the characteristics of electronic components such as MOS transistors becomes considerable.

An increase in tensile stress lowers hole mobility. In a CMOS field effect transistor (FET) integrated circuit, n-channel MOS (NMOS) FETs as well as p-channel MOS (PMOS) FETs are formed. As tensile stress which the etching stopper applies to a channel region is increased, although the characteristics of NMOSFET are improved, the characteristics of PMOSFET are degraded.

JP-A-2003-86708 proposes using a stress controlling film, covering NMOSFET with a film having tensile stress and covering PMOSFET with a film having compressive stress. The characteristics of CMOSFET can be improved by applying tensile stress to NMOSFET and compressive stress to PMOSFET.

JP-A-2006-13322 describes a relation between drain current and stresses in a gate length direction, a gate width direction and a depth direction. A PMOSFET drive performance is improved by compressive stress in the gate length direction and tensile stress in the gate width direction. It is proposed that a compressive stress film is formed covering PMOSFET and compressive stress along the gate width direction is released in the region outside the active region.

### SUMMARY OF THE INVENTION

An object of this invention is to provide a CMOS semiconductor device and its manufacture method capable of improving device performance by the layout of stress films.

It is another object of this invention to provide a CMOS semiconductor device and its manufacture method capable of increasing drive performance by paying attention to a border between a tensile stress film and a compressive stress film formed above the CMOS semiconductor device.

According to one aspect of the present invention, there is provided a CMOS semiconductor device comprising:

a semiconductor substrate;

an isolation region formed in a surface layer of the semiconductor substrate to define an NMOSFET active region and a PMOSFET active region adjacent to each other;

an NMOSFET structure formed in the NMOSFET active region;

a PMOSFET structure formed in the PMOSFET active region;

a tensile stress film formed covering the NMOSFET structure; and

a compressive stress film formed covering the PMOSFET structure

wherein a border between the tensile stress film and the compressive stress film is set nearer to the PMOSFET active region than the NMOSFET active region along a gate width direction.

According to another aspect of the present invention, there is provided a CMOS semiconductor device manufacture method comprising the steps of:

(a) forming an isolation region in a surface layer of a semiconductor substrate to define an NMOSFET active region and a PMOSFET active region adjacent to each other;

(b) forming an NMOSFET structure in the NMOSFET active region and a PMOSFET structure in the PMOSFET active region;

(c) forming a tensile stress film covering the NMOSFET structure and a compressive stress film covering the PMOSFET structure to set a border between the tensile stress film and the compressive stress film nearer to the PMOSFET active region than the NMOSFET active region along a gate width direction.

It has been found that drive performance of CMOSFET changes with the position of a border between the tensile stress film and compressive stress film. The drive performance can be improved by setting the border between the tensile stress film and comparative stress film nearer to the PMOSFET active region than the NMOSFET active region.

### BRIEF DESCRIPTION OF THE DRAWINGS

FIGS. 1A, 1B and 1C are a cross sectional view and plan views showing the structure of samples, and FIG. 1D is a graph showing measurement results of the samples.

FIGS. 2AW to 2FW and FIGS. 2AL to 2FL are cross sectional views illustrating main processes of a CMOS semiconductor device manufacture method according to an embodiment of the present invention.

### DESCRIPTION OF THE PREFERRED EMBODIMENTS

In a micro MOSFET having a gate length of 100 nm or shorter, parasitic resistance and capacitance increase and high performance becomes difficult. If a tensile film is formed on NMOSFET and a compressive film is formed on PMOSFET, drive performance can be improved. Since stress becomes relatively large in a micro semiconductor structure, it is possible to improve the drive performance.

First, a phenomenon experimentally found by the present inventor will be described.

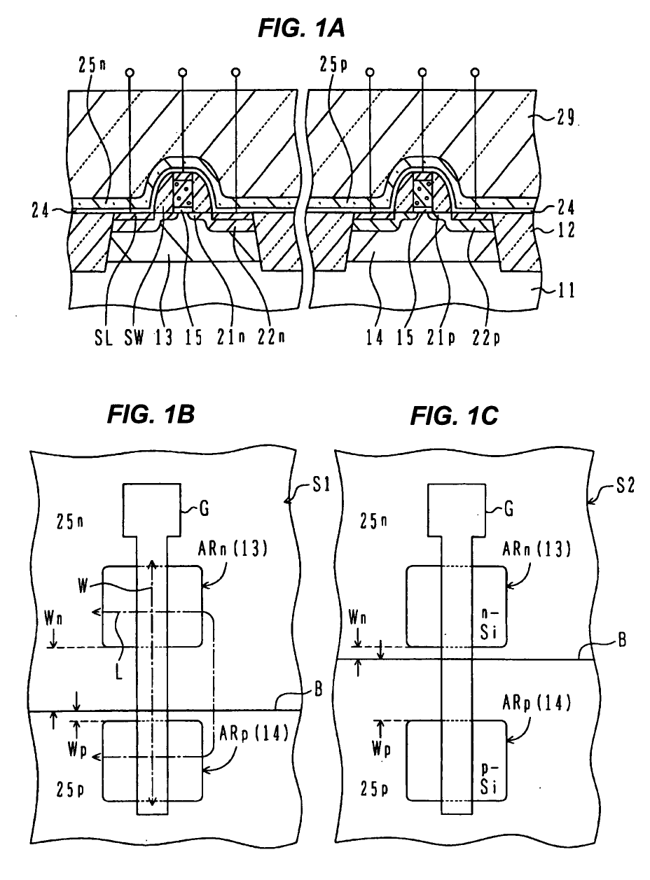

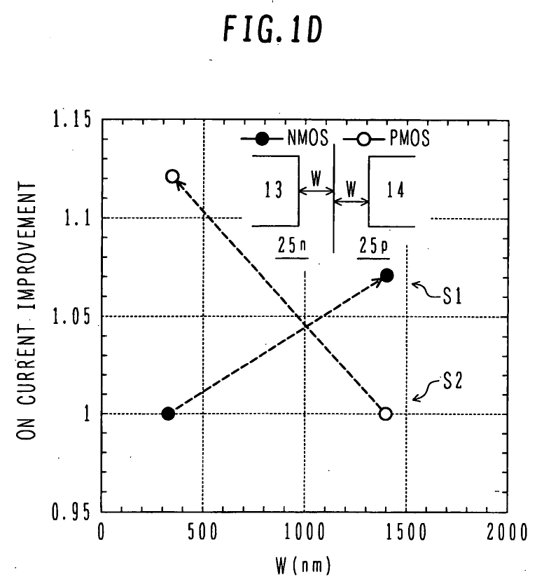

FIG. 1A is a schematic cross sectional view showing the structure of a complementary MOS (CMOS) semiconductor device. A shallow trench 12 as an isolation region is formed to a depth of about 350 nm from the surface of a silicon substrate 11 serving as a semiconductor substrate, and an insulating film such as a silicon oxide film is buried in the trench to form a shallow trench isolation (STI) 12.

Well forming impurities are selectively implanted into active regions defined by STI 12 to form a p-type well 13 for forming an n-channel MOS (NMOS) FET and an n-type well 14 for forming a p-channel MOS (PMOS) FET. A gate insulating film 15 is formed on the surface of the active region, and a polysilicon film as a gate electrode is formed on the gate insulating film, to form an insulated gate electrode structure through patterning. A gate length along a lateral direction in the drawing is 35 nm.

In the p-type well 13, n-type impurity ions are implanted shallowly to form n-type extension regions 21n, and in the n-type well 14, p-type impurity ions are implanted shallowly to form p-type extension regions 21p. Thereafter, an insulating film such as a silicon oxide film is deposited on the whole substrate surface, and anisotropic etching is performed to form sidewall spacers SW on side walls of the insulated gate electrode structures in an NMOSFET area and in a PMOSFET region.

In the p-type well region 13, n-type impurity ions are implanted deeply to form n-type source/drain diffusion layers 22n, and in the n-type well region 14, p-type impurity ions are implanted deeply to form p-type source/drain diffusion layers 22p. A metal layer of nickel or the like is deposited on the exposed silicon surface, and a silicidation process is performed to form silicide regions SL.

Thereafter, in the p-type well region 13, a silicon nitride film 25n having tensile stress and a thickness of 80 nm is formed covering the gate electrode, and in the n-type well region 14, a silicon nitride film 25p having compressive stress and a thickness of 80 nm is formed covering the gate electrode. The tensile stress was 1.7 GPa, and the compressive stress was 2.5 GPa. A silicon oxide film 29 as an interlayer insulating film is formed on the silicon nitride films 25n and 25p. Contact holes are formed through the silicon oxide film 29 and silicon nitride film 25, and electrodes (conductive plugs) contacting respective regions are formed. In this manner, a basic CMOS structure is formed including an NMOSFET structure and a PMOSFET structure.

FIGS. 1B and 1C are schematic top views showing the plan layout of CMOS structures of two samples. An NMOSFET active region ARn (p-type well) 13 and a PMOSFET active region ARp (n-type well) 14 are laid out vertically, and a common gate electrode G is disposed traversing the central area of each active region vertically in the drawing. On both sides of the gate electrodes, n-type impurities are doped in NMOSFET, and p-type impurities are doped in PMOSFET to form source/drain regions each having a length of 1 μm along a gate length direction or lateral direction in the drawing. The structure described above is common to both the samples.

Wn represents a distance from a border B between the tensile stress film 25n and compressive stress film 25p to the NMOSFET active region ARn, and Wp represents a distance between the border B to the PMOSFET active region ARp. In the first sample S1 shown in FIG. 1B, Wn is about 1390 nm and Wp is about 330 nm. In the second sample S2 shown in FIG. 1C, Wn is about 330 nm and Wp is about 1390 nm, reversing the relation between Wn and Wp of the first sample. Drain current (on-current) was measured by applying voltage of 1 V across source/drain regions of NMOSFET and PMOSFET of each sample and an on-voltage to the gate.

FIG. 1D is a graph showing the measurement results. Solid circles represent NMOSFETs, and open circles represent PMOSFETs. If the on-currents of NMOSFET and PMOSFET of the second sample S2 are used as a reference (1.0), the on-current of PMOSFET of the first sample S1 is about 1.12, and the on-current of NMOSFET of the first sample S1 is abut 1.07. It has been found that depending upon only the position of the border B between the tensile stress film 25n and compressive stress film 25p on the substrate, the on-current changes about 10%. It can be considered that a large on-current can be obtained if the border B between the tensile stress film 25n and compressive stress film 25p on the substrate is set apart from the NMOSFET active region ARn and near to the PMOSFET active region ARp. A deviation (Wn−Wp)/(Wn+Wp)=(1390−330)/(1390+330) of Wn and Wp of the first sample is about 0.62. The deviation of the second sample is about −0.62. It is expected that the on-currents of both NMOSFET and PMOSFET can be increased distinctly if the deviation is about +0.3 or larger. The deviation (Wn−Wp)/(Wn+Wp) is more preferably about +0.5 or larger.

It is known that a drain current of NMOSFET can be increased by applying tensile stress along the gate length direction and along the gate width direction whereas a drain current of PMOSFET can be increased by applying compressive stress along the gate length direction and tensile stress along the gate width direction. Tensile stress along the gate width direction is therefore preferable for both NMOSFET and PMOSFET. It can be considered that if the border between the tensile stress silicon nitride film and compressive stress silicon nitride film is set apart from the NMOSFET active region and near to the PMOSFET region, an area of the tensile stress film along the gate width direction becomes large in the NMOSFET active region so that tensile stress is enhanced, and an area of the compressive film becomes small in the PMOSFET active region so that compressive stress is reduced. This stress change may be ascribed to an increase in a drain current of NMOSFET and PMOSFET. This assumption matches the measurement results shown in FIG. 1D.

The first sample S1 shown in FIG. 1B constitutes the structure of the embodiment of the present invention. Detailed description will now be made on a CMOS semiconductor device manufacture processes according to the embodiment. In FIG. 1B, a gate width direction is represented by W and a gate length direction is represented by L, and the following cross sectional views are taken along these directions W and L.

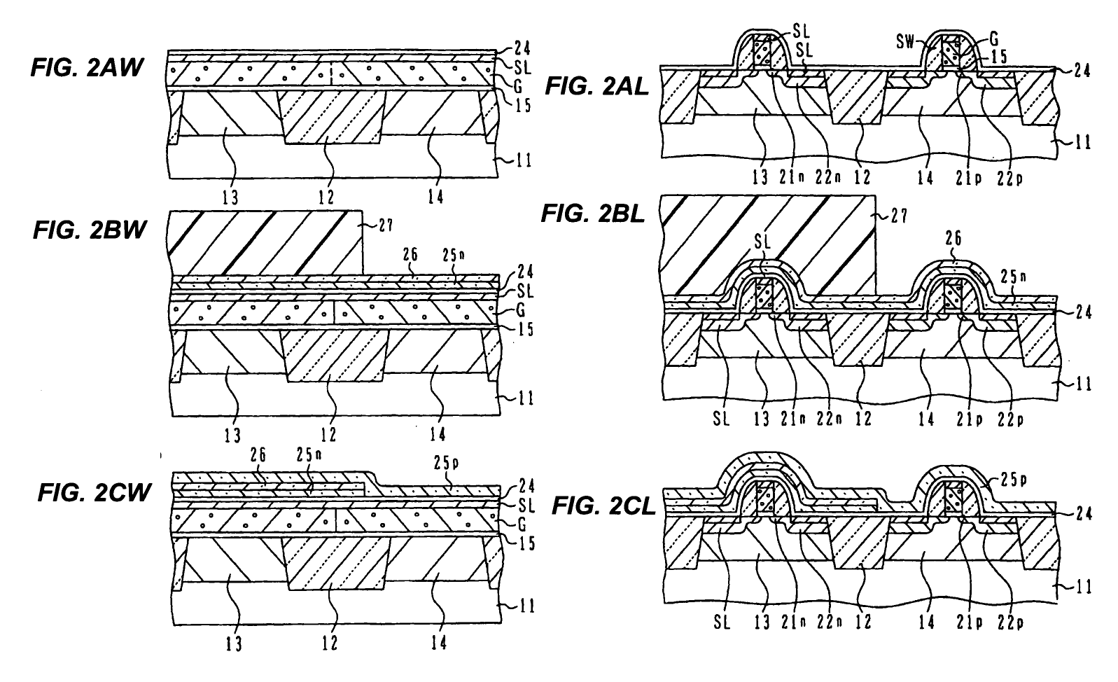

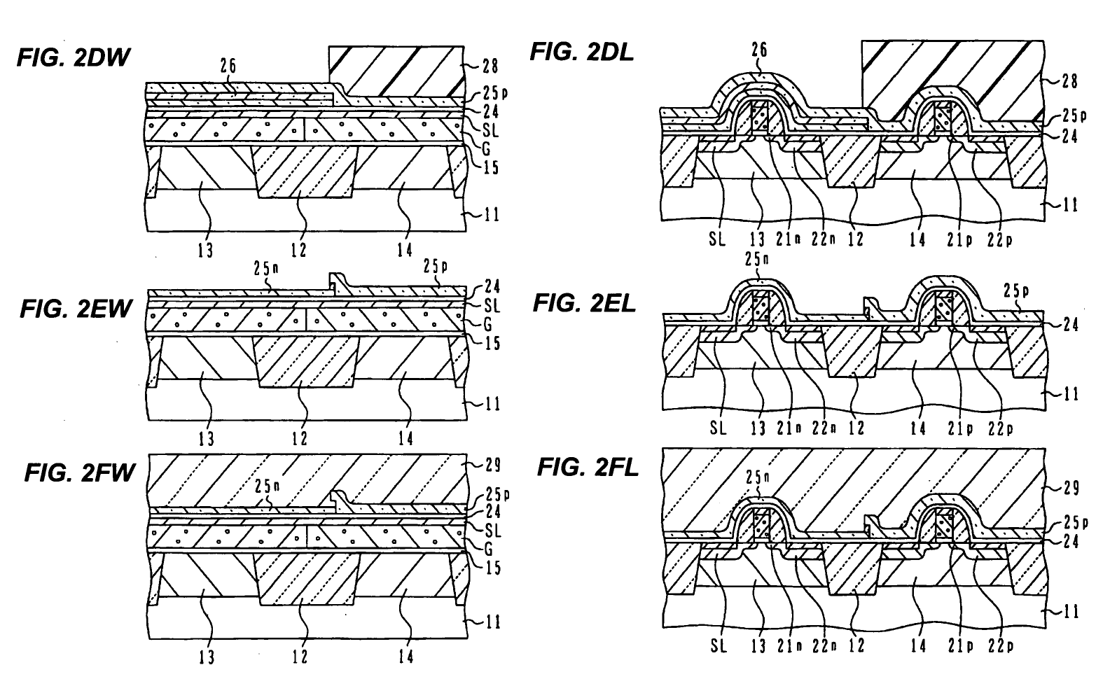

FIGS. 2AW to 2FW are cross sectional views taken along the gate width direction and traversing an n-type well 14 and a p-type well 13. FIGS. 2AL to 2FL are cross sectional views of the n-type well 14 and p-type well 13 taken along the gate length (source/drain) direction L, coupled through STI region.

As shown in FIGS. 2AW and 2AL, a shallow trench is formed in a surface layer of a p-type silicon substrate 11 to define active regions, an insulating film is deposited to bury the shallow trench, and an unnecessary insulating film on the active region is removed by chemical mechanical polishing (CMP) or the like to form a shallow trench isolation (STI) 12. An NMOSFET region and a PMOSFET region are selectively exposed by a resist mask, and impurity ions are implanted in these regions to form a p-type well 13 and an n-type well 14.

The surface of the active region is thermally oxidized and nitridized to form a silicon oxynitride film 15 having a thickness of 1.2 nm as a gate insulating film. Instead of the silicon oxynitride film, a lamination of a silicon oxide film and a silicon nitride film or a lamination of a silicon oxide film and a high-k film such as HfO₂ formed thereon may be used as the gate insulating film.

A polysilicon layer G having a thickness of, e.g., 140 nm, is formed on the gate insulating film 15. A cap silicon oxide layer having a thickness of, e.g., about 50 nm, may be stacked on the polysilicon layer. A photoresist pattern is formed on the polysilicon layer G, and the polysilicon layer G and gate insulating film 15 are patterned. If the cap silicon oxide layer is formed, this layer can be used as a hard mask. In this manner, an insulated gate electrode structure is formed.

The n-type well 14 is covered with a photoresist pattern, and n-type impurity ions, e.g., As ions, are implanted into the p-type well 13 at an acceleration energy of 2 keV and a dose of 5×10¹⁴ cm⁻² to form n-type shallow extension regions 21n on both sides of the insulated gate electrode structure. The p-type well 13 is covered with a photoresist pattern, and p-type impurity ions, e.g., B ions, are implanted into the n-type well 14 at an acceleration energy of 1 keV and a dose of 4×10¹⁴ cm⁻² to form p-type shallow extension regions 21p on both sides of the insulated gate electrode structure. Implanted ions are activated to obtain extension regions 21n and 21p having a depth of about 30 nm. Although the extension regions slightly crawl under the insulated gate electrode structure, the phrase “on both sides of the insulated gate electrode structure” is used including such a crawl structure.

A silicon oxide layer having a thickness of about 80 nm is deposited on the surface of the silicon substrate 11, for example, by CVD, and reactive ion etching (RIE) is performed to leave sidewall spacers SW on the sidewalls of the gate electrode. If the cap silicon oxide layer is formed, this layer is removed by this process.

The PMOSFET active region 14 is covered with a mask, and n-type impurity ions, e.g., P ions, are implanted into the NMOSFET active region 13 at an acceleration energy of 10 keV and a dose of 4×10¹⁵ cm⁻² to form n-type source/drain diffusion layers 22n. The source/drain diffusion layers are therefore formed on both sides of the sidewall spacers SW and insulated gate electrode structure, and n-type impurities are doped also into the gate electrode. Although the source/drain diffusion layers slightly crawl under the sidewall spacers SW, the phrase “on both sides of the sidewall spacers” is used including such a crawl structure.

The NMOSFET active region is covered with a mask, and p-type impurity ions, e.g., B ions, are implanted into the PMOSFET active region 14 at an acceleration energy of 6 keV and a dose of 4×10¹⁵ cm⁻² to form p-type source/drain diffusion layers 22p. The source/drain diffusion layers are therefore formed, and p-type impurities are doped also into the gate electrode.

A Ni film is deposited from an upper position, for example, by sputtering, first silicidation reaction is performed, thereafter, unreacted unnecessary metal layers are washed out, and secondary silicidation reaction is performed to form low resistance silicide layers SL. A silicon oxide film 24 having a thickness of 5 to 20 nm is deposited on the substrate by CVD. This silicon oxide film 24 functions as a protective film of the silicide layer SL. The silicide layer SL and silicon oxide film 24 are not essential constituent elements.

As shown in FIGS. 2BW and 2BL, a silicon nitride film 25n having tensile stress is deposited by thermal CVD, for example, under the following conditions. A silicon nitride film having a thickness of, e.g., 80 nm, is formed by flowing dichlorsilane (SiCl₂H₂), silane (SiH₄) or disilane (Si₂H₆) at a flow rate of 5 to 50 sccm as silicon source gas, NH₃ at a flow rate of 500 to 10000 sccm as nitrogen source gas and N₂ or Ar at a flow rate of 500 to 10000 sccm, under the conditions of a pressure of 0.1 to 400 torr and a temperature of 500 to 700° C. A tensile stress is, for example, 1.7 GPa. A silicon oxide film 26 having a thickness of, e.g., 10 nm, is formed on the silicon nitride film 25n, for example, by using TEOS. The silicon oxide film 26 is sufficient if it provides an etching stopper function, and may be formed by various methods.

The NMOSFET active region is covered with a resist mask 27. The resist mask 27 defines the region where the silicon nitride film 25n having tensile stress is to be left. The border B shown in FIGS. 1B and 1C is determined by the edge of the silicon nitride film 25n. Therefore, the edge of the resist mask 27 is set apart from the NMOSFET active region and near to the PMOSFET active region. The exposed silicon oxide film 26 is removed by RIE using, for example, C₄F₈/Ar/O₂ as etching gas. By changing etching gas, for example, to CHF₃/Ar/O₂, the exposed silicon nitride film 25n is etched and removed by RIE. The resist mask 27 is thereafter removed. A PMOSFET structure is exposed.

As shown in FIGS. 2CW and 2CL, a silicon nitride film 25p having compressive stress is formed by plasma CVD under the following conditions. For example, the plasma CVD is performed by flowing as source gasses SiH₄ at a flow rate of 100 to 1000 sccm, NH₃ at a flow rate of 500 to 10000 sccm and N₂ or Ar at a flow rate of 500 to 10000 sccm under the conditions of a pressure of 0.1 to 400 torr, a temperature of 500 to 700° C. and an RF power of 100 to 1000 W. The silicon nitride film 25p is therefore deposited having a thickness of, e.g., 80 nm. A compressive stress is, for example, 2.5 GPa.

As shown in FIG. 2DW and 2DL, the PMOSFET active region is covered with a resist mask 28. The resist mask 28 is patterned to align its edge with the edge of the left tensile stress silicon nitride film 25n. In this embodiment, the whole surface of the substrate is covered with these two silicon nitride films 25n and 25p, so that it is possible to provide a function of preventing moisture and oxygen from entering the substrate. The compressive stress silicon nitride film 25p exposed from the resist mask is etched and removed. For this etching, the silicon oxide film 26 can be used as an etching stopper. Etching the silicon nitride film is performed by RIE using, for example, CHF₃/Ar/O₂ etchant. The exposed silicon oxide film 26 is removed by RIE using C₄F₈/Ar/O₂ as etchant. The resist mask 28 is thereafter removed.

Although the tensile stress film and compressive stress film are made of a silicon nitride film having a thickness of 80 nm, a thickness of the silicon nitride stress film may be selected from a range of 40 nm to 100 nm. The tensile stress silicon nitride film is formed and selectively etched, and thereafter the compressive stress silicon nitride film is formed. This order may be reversed. Although the silicon nitride film having a desired stress formed on the silicon nitride film having an opposite polarity stress is removed, this film may be left unetched although the advantages of the invention are lowered. It is possible to selectively implant ions such as Ge to selectively relax the stress of the upper side film.

As shown in FIGS. 2FW and 2FL, a silicon oxide film 29 is deposited on the silicon nitride films 25n and 25p, by using a TEOS silicon oxide film or a high density plasma (HDP) silicon oxide film. The silicon nitride film 25 and silicon oxide film 29 constitute an interlayer insulating film. Contact holes are thereafter formed through the interlayer insulating film, and source/drain electrodes and the like are derived.

In the embodiment described above, NMOSFET is covered with the tensile stress film and PMOSFET is covered with the compressive stress film. The performances of both NMOSFET and PMOSFET can be improved by stress. Further, the border between the tensile stress film and compressive stress film is set apart from the NMOSFET active region and near to the PMOSFET active region. This layout further improves the on-currents of NMOSFET and PMOSFET.

The present invention has been described in connection with the preferred embodiments. The invention is not limited only to the above embodiments. It will be apparent to those skilled in the art that other various modifications, improvements, combinations, and the like can be made.

What are claimed are:

1. A CMOS semiconductor device comprising:
a semiconductor substrate;
an isolation region formed in a surface layer of said semiconductor substrate to define an NMOSFET active region and a PMOSFET active region adjacent to each other;
an NMOSFET structure formed in said NMOSFET active region;
a PMOSFET structure formed in said PMOSFET active region;
a tensile stress film covering said NMOSFET structure; and
a compressive stress film covering said PMOSFET structure
wherein a border between said tensile stress film and said compressive stress film is set nearer to said PMOSFET active region than said NMOSFET active region along a gate width direction.

2. The CMOS semiconductor device according to claim 1, wherein a deviation (Wn−Wp)/(Wn+Wp) is +0.3 or larger where Wn is a distance from said border to said NMOSFET active region and Wp is a distance from said border to said PMOSFET active region.

3. The CMOS semiconductor device according to claim 2, wherein the deviation (Wn−Wp)/(Wn+Wp) is +0.5 or larger.

4. The CMOS semiconductor device according to claim 1, wherein said tensile stress film and said compressive stress film are each made of a silicon nitride film.

5. The CMOS semiconductor device according to claim 1, wherein said isolation region is made of STI, said tensile stress film and said compressive stress film have an overlap above said isolation region, and said border is a position where said stress films contact each other on a surface of said semiconductor substrate.

6. The CMOS semiconductor device according to claim 1, wherein said NMOSFET structure and said PMOSFET structure have a common gate electrode.

7. The CMOS semiconductor device according to claim 6, wherein said gate electrode has a gate length of 100 nm or shorter.

8. The CMOS semiconductor device according to claim 6, wherein said tensile stress film and said compressive stress film have a partial overlap and the border above said semiconductor substrate crosses said common gate electrode.

9. The CMOS semiconductor device according to claim 8, wherein a deviation (Wn−Wp)/(Wn+Wp) is +0.5 or larger where Wn is a distance from said border to said NMOSFET active region and Wp is a distance from said border to said PMOSFET active region.

10. The CMOS semiconductor device according to claim 6, wherein one of said tensile stress film and said compressive stress film selectively covers said NMOSFET structure or said PMOSFET structure, and the other of said tensile stress film and said compressive stress film is formed over a whole surface of said semiconductor substrate and has a stress selectively relaxed on said one stress film.

11. A CMOS semiconductor device manufacture method comprising the steps of:
(a) forming an isolation region in a surface layer of a semiconductor substrate to define an NMOSFET active region and a PMOSFET active region adjacent to each other;
(b) forming an NMOSFET structure in said NMOSFET active region and a PMOSFET structure in said PMOSFET active region;
(c) forming a tensile stress film covering said NMOSFET structure and a compressive stress film covering said PMOSFET structure to set a border between said tensile stress film and said compressive stress film nearer to said PMOSFET active region than said NMOSFET active region along a gate width direction.

12. The CMOS semiconductor device manufacture method according to claim 11, wherein said tensile stress film and said compressive stress film in said step (c) are each made of a silicon nitride film.

13. The CMOS semiconductor device manufacture method according to claim 12, wherein said step (c) forms said tensile stress film by thermal CVD and said compressive stress film by plasma CVD.

14. The CMOS semiconductor device manufacture method according to claim 13, wherein said steps (a) and (b) form a common gate electrode, and said step (c) forms said border crossing said common gate electrode.

15. The CMOS semiconductor device manufacture method according to claim 14, wherein said step (c) forms a buffer insulating film after one of said tensile stress film and said compressive stress film is formed.

16. The CMOS semiconductor device manufacture method according to claim 15, wherein said step (c) removes an unnecessary portion of said buffer insulting film and one of said stress films, and thereafter forms the other of said stress films.

17. The CMOS semiconductor device manufacture method according to claim 16, wherein said step (c) further removes an unnecessary portion of said other of said stress films.

18. The CMOS semiconductor device manufacture method according to claim 17, wherein said step (c) selectively removes said other of said stress films to leave said other of said stress films partially overlapping said one of said stress films.

19. The CMOS semiconductor device manufacture method according to claim 16, wherein said step (c) relaxes a stress of said other of said stress films on said one of said stress films.

20. The CMOS semiconductor device manufacture method according to claim 19, wherein said stress relaxation is realized by ion implantation.
